(19) United States
(12) Patent Application Publication
(10) Pub. No.: US 2025/0142720 A1
(43) Pub. Date: May 1, 2025

(54) IMAGING UNIT

(71) Applicant: NIDEC PRECISION CORPORATION, Tokyo (JP)

(72) Inventors: Makoto HAMAWAKI, Tokyo (JP); Shigemi TAKAHASHI, Tokyo (JP)

(21) Appl. No.: 18/928,185

(22) Filed: Oct. 28, 2024

(30) Foreign Application Priority Data
Nov. 1, 2023 (JP) 2023-187491

(51) Int. Cl. H05K 1/02; H04N 23/54

(52) U.S. Cl. CPC H05K 1/028; H04N 23/54

(57) ABSTRACT

An imaging unit includes a main substrate, a lens module including an image sensor mounted on the main substrate, and a flexible printed circuit board containing wiring electrically connected to the image sensor. The flexible printed circuit board includes bent portions each including bends and extending from the main substrate substantially in the Z-direction. One of the bent portions includes a plurality of spans extending in the X-direction and arranged in the Z-direction, and a connector connecting the spans adjacent to each other in the Z-direction. The other of the bent portions includes a plurality of spans extending in the Y-direction and arranged in the Z-direction, and a connector connecting the spans adjacent to each other in the Z-direction.

### RELATED APPLICATIONS

The present application claims priority to Japanese Application Number 2023-187491, filed Nov. 1, 2023, the disclosure of which is hereby incorporated by reference herein in its entirety.

### BACKGROUND

### Technical Field

The present invention relates to an imaging unit.

### Description of the Background

To reduce susceptibility to camera shake during photographing, many cameras include a lens module, including an image sensor, that is movable relative to the camera body in a plane perpendicular to the optical axis. Such a camera includes a flexible printed circuit board that is flexibly deformable to reliably connect the image sensor and an external electronic component when the lens module moves (refer to, for example, Patent Literature 1).

Nowadays, for more advanced image stabilization, the lens module may be rotatable about the pitch axis and the yaw axis relative to the camera body, in addition to being movable in the plane perpendicular to the optical axis. However, the known flexible printed circuit board described above is to be used for the lens module movable in the plane perpendicular to the optical axis. Thus, when the lens module rotates about the yaw axis or the pitch axis, the flexible printed circuit board twists and thus has lower durability. In addition, the flexible printed circuit board receives different loads when the lens module rotates about the pitch axis and when the lens module rotates about the yaw axis. The flexible printed circuit board thus has multiple resonance points, which may be difficult to control.

### CITATION LIST

### Patent Literature

Patent Literature 1: Japanese Unexamined Patent Application Publication No. 2007-122020

### BRIEF SUMMARY

In response to the above issue, one or more aspects of the present invention are directed to an imaging unit that allows a flexible printed circuit board to be less susceptible to the rotation of a lens module.

An imaging unit according to one aspect of the present invention allows a flexible printed circuit board to be less susceptible to the rotation of a lens module. The imaging unit includes a main substrate having a first surface and a second surface opposite to the first surface, a lens module including at least one lens having an optical axis in a first direction and an image sensor mounted on the first surface of the main substrate, and a flexible printed circuit board containing wiring electrically connected to the image sensor in the lens module. The flexible printed circuit board includes a first bent portion including bends and extending from the main substrate substantially in the first direction, and a second bent portion including bends and extending from the main substrate substantially in the first direction. The first bent portion has a first width in a second direction perpendicular to the first direction. The second bent portion has a second width in a third direction perpendicular to the first direction and to the second direction. The first bent portion in the flexible printed circuit board includes a plurality of first spans extending in the third direction and arranged in the first direction, and at least one first connector connecting the plurality of first spans adjacent to each other in the first direction. The second bent portion in the flexible printed circuit board includes a plurality of second spans extending in the second direction and arranged in the first direction, and at least one second connector connecting the plurality of second spans adjacent to each other in the first direction.

The imaging unit according to the above aspect of the present invention includes the flexible printed circuit board including the first bent portion and the second bent portion each including the bends and extending from the base substantially in the first direction. Thus, when the image sensor rotates about an axis (e.g., the pitch axis) in the second direction or when the image sensor rotates about an axis (e.g., the yaw axis) in the third direction, the first bent portion with the bends and the second bent portion with the bends deform flexibly to reduce a load on the entire flexible printed circuit board.

### BRIEF DESCRIPTION OF DRAWINGS

FIG. 1 is a perspective view of an imaging unit according to one embodiment of the present invention.

FIG. 2 is a front view of the imaging unit shown in FIG. 1.

FIG. 3 is a right side view of the imaging unit shown in FIG. 1.

FIG. 4 is a bottom view of the imaging unit shown in FIG. 1.

### DETAILED DESCRIPTION

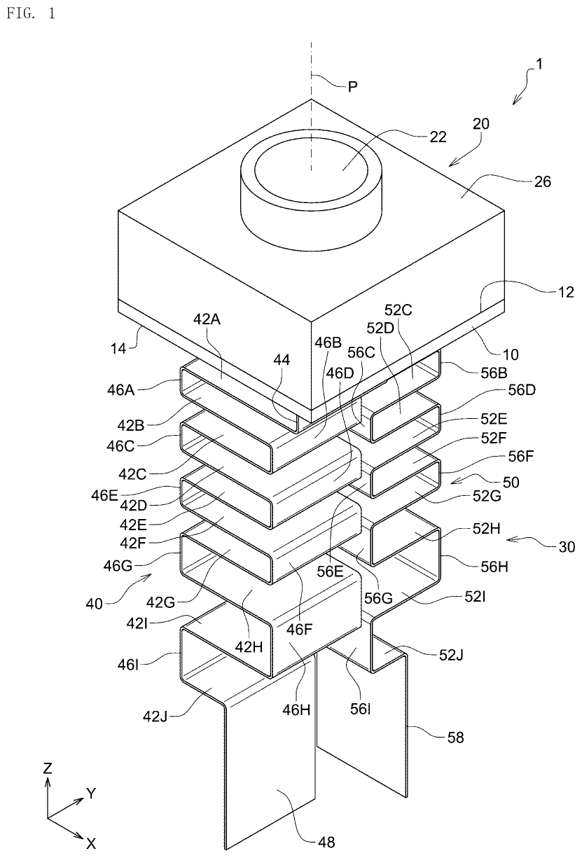

An imaging unit according to one or more embodiments of the present invention will now be described in detail with reference to FIGS. 1 to 4. In FIGS. 1 to 4, like reference numerals denote like or corresponding components. Such components will not be described repeatedly. In FIGS. 1 to 4, the scale and dimensions of each component may be exaggerated, or one or more components may not be shown. Unless otherwise specified, the terms such as first and second will be used simply to distinguish the components and will not represent a specific order or sequence.

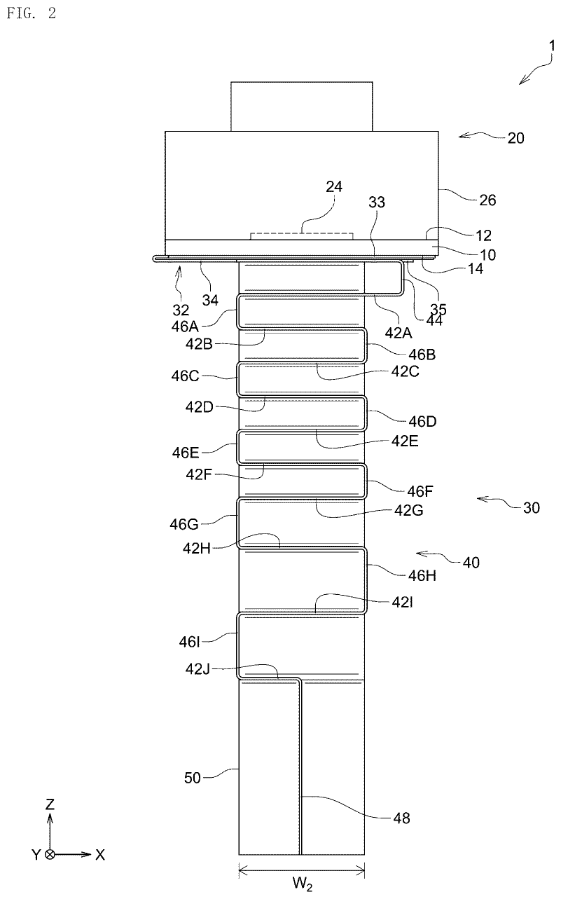

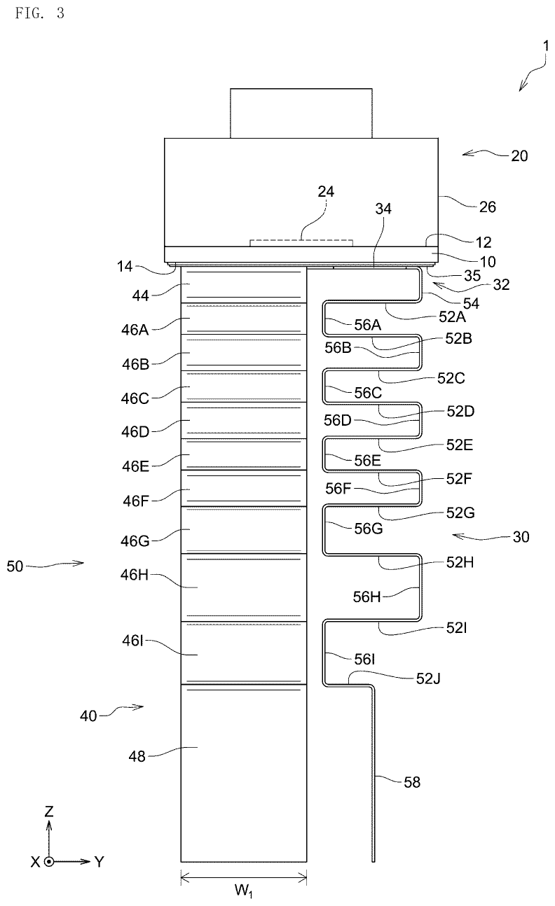

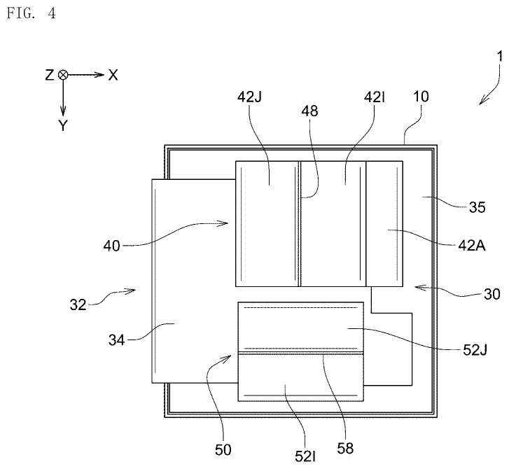

FIG. 1 is a perspective view of an imaging unit 1 according to one embodiment of the present invention. FIG. 2 is a front view of the imaging unit 1. FIG. 3 is a right side view of the imaging unit 1. FIG. 4 is a bottom view of the imaging unit 1. As shown in FIGS. 1 to 4, the imaging unit 1 according to the present embodiment includes a main substrate 10 that is a rectangular plate extending along an XY plane, a lens module 20 mounted on one surface 12 (first surface) of the main substrate 10, and a flexible printed circuit board 30 attached to another surface 14 (second surface) of the main substrate 10. The lens module 20 includes a housing 26 accommodating at least one lens 22 and an image sensor 24 mounted on the surface 12 of the main substrate 10. Examples of the image sensor 24 include a charge-coupled device (CCD) sensor and a complementary metal-oxide-semiconductor (CMOS) sensor. The lens 22 has an optical axis P in the Z-direction (first direction). To allow the image sensor 24 to be less susceptible to camera shake during photographing, the main substrate 10 and the lens module 20 in the present embodiment are rotatable about the X-axis (e.g., the yaw axis) and the Y-axis (e.g., the pitch axis) relative to an external substrate or an external electronic device. For ease of explanation in the present embodiment, up or upward refers to the positive Z-direction in FIG. 1, and down or downward refers to the negative Z-direction in FIG. 1.

The flexible printed circuit board 30 electrically connects the image sensor 24 in the lens module 20 to the external substrate or the external electronic device (not shown). The flexible printed circuit board 30 contains wiring (not shown) electrically connected to the image sensor 24. When the main substrate 10 and the lens module 20 rotate about the X-axis or the Y-axis to reduce susceptibility to camera shake, the flexible printed circuit board 30 deforms flexibly to electrically connect the image sensor 24 to the external board or the external electronic device. The structure of the flexible printed circuit board 30 will now be described in detail.

As shown in FIGS. 1 to 4, the flexible printed circuit board 30 includes a base 32 connected to the surface 14 of the main substrate 10 and two bent portions 40 and 50 each including bends and extending from the base 32 substantially in the negative Z-direction. The base 32 includes a fixed portion 33 fixed to the surface 14 of the main substrate 10, a folded portion 34 folded back from the fixed portion 33, and a heat dissipation sheet 35 fastened between the fixed portion 33 and the folded portion 34. The heat dissipation sheet 35 may be, for example, a heat dissipation sheet containing graphite. An adhesive sheet or an adhesive may be located between the fixed portion 33 and the folded portion 34.

The bent portion 40 (first bent portion) includes a strip portion with a constant width W₁ (refer to FIG. 3) in the Y-direction (second direction) that is bent alternately. More specifically, as shown in FIG. 2, the bent portion 40 includes multiple spans 42A to 42J (first spans) arranged in the Z-direction, a basal end 44 (first basal end) connecting the folded portion 34 and the span 42A, multiple connectors 46A to 46I (first connectors) connecting the spans 42A to 42J adjacent to one another in the Z-direction, and a terminal end 48 connectable to the external substrate or the external electronic device. Hereafter, the spans 42A to 42J may be collectively referred to as the spans 42, and the connectors 46A to 46I may be collectively referred to as the connectors 46.

The connectors 46A to 46I alternate with one another in the X-direction (third direction) across the spans 42A to 42J arranged in the Z-direction. More specifically, the first connector 46A is located in the negative X-direction from the spans 42A and 42B, the second connector 46B is located in the positive X-direction from the spans 42B and 42C, the third connector 46C is located in the negative X-direction from the spans 42C and 42D, the fourth connector 46D is located in the positive X-direction from the spans 42D and 42E, the fifth connector 46E is located in the negative X-direction from the spans 42E and 42F, the sixth connector 46F is located in the positive X-direction from the spans 42F and 42G, the seventh connector 46G is located in the negative X-direction from the spans 42G and 42H, the eighth connector 46H is located in the positive X-direction from the spans 42H and 42I, and the ninth connector 46I is located in the negative X-direction from the spans 42I and 42J. In the present embodiment, as shown in FIG. 2, the multiple spans 42 have the same length in the X-direction. The spans 42 have their middles in the X-direction aligned with the middle of the main substrate 10 in the X-direction.

The connectors 46A to 46I are gradually longer in the Z-direction downward from the base 32. For example, the connector 46B is longer than the connector 46A in the Z-direction, and the connector 46C is longer than the connector 46B in the Z-direction.

The bent portion 50 (second bent portion) includes a strip portion with a constant width W₂ (refer to FIG. 2) in the X-direction (third direction) that is bent alternately. More specifically, as shown in FIG. 3, the bent portion 50 includes multiple spans 52A to 52J (second spans) arranged in the Z-direction, a basal end 54 (second basal end) connecting the folded portion 34 and the span 52A, multiple connectors 56A to 56I (second connectors) connecting the spans 52A to 52J adjacent to one another in the Z-direction, and a terminal end 58 connectable to the external substrate or the external electronic device. Hereafter, the spans 52A to 52J may be collectively referred to as the spans 52, and the connectors 56A to 56I may be collectively referred to as the connectors 56.

The connectors 56A to 56I alternate with one another in the Y-direction (second direction) across the spans 52A to 52J arranged in the Z-direction. More specifically, the first connector 56A is located in the negative Y-direction from the spans 52A and 52B, the second connector 56B is located in the positive Y-direction from the spans 52B and 52C, the third connector 56C is located in the negative Y-direction from the spans 52C and 52D, the fourth connector 56D is located in the positive Y-direction from the spans 52D and 52E, the fifth connector 56E is located in the negative Y-direction from the spans 52E and 52F, the sixth connector 56F is located in the positive Y-direction from the spans 52F and 52G, the seventh connector 56G is located in the negative Y-direction from the spans 52G and 52H, the eighth connector 56H is located in the positive Y-direction from the spans 52H and 52I, and the ninth connector 56I is located in the negative Y-direction from the spans 52I and 52J. In the present embodiment, as shown in FIG. 3, the multiple spans 52 have the same length in the Y-direction.

The connectors 56A to 56I are gradually longer in the Z-direction downward from the base 32. For example, the connector 56B is longer than the connector 56A in the Z-direction, and the connector 56C is longer than the connector 56B in the Z-direction.

In the present embodiment, as shown in FIG. 2, the multiple spans 42 in the bent portion 40 have the same length in the X-direction, and the length is substantially equal to the width W₂ of the bent portion 50 in the X-direction. Similarly, as shown in FIG. 3, the multiple spans 52 in the bent portion 50 have the same length in the Y-direction. However, the multiple spans 42 in the bent portion 40 may have different lengths in the X-direction, and the multiple spans 52 in the bent portion 50 may have different lengths in the Y-direction.

Although the main substrate 10 and the lens module 20 are rotatable about the X-axis and the Y-axis as described above, the flexible printed circuit board 30 in the present embodiment includes the bent portions 40 and 50 each including the bends and extending from the base 32 substantially in the negative Z-direction. Thus, when, for example, the main substrate 10 and the lens module 20 (image sensor 24) rotate about the Y-axis (e.g., the pitch axis), the bent portion 40 with the bends deforms flexibly to reduce a load on the entire flexible printed circuit board 30. Similarly, when the main substrate 10 and the lens module 20 rotate about the X-axis (e.g., the yaw axis), the bent portion 50 with the bends deforms flexibly to reduce a load on the entire flexible printed circuit board 30. In this manner, the imaging unit 1 according to the present embodiment can reduce the load on the entire flexible printed circuit board 30 when the main substrate 10 and the lens module 20 rotate about the X-axis or the Y-axis.

In the present embodiment, as shown in FIG. 2, the basal end 44 and the connectors 46 in the bent portion 40 extend straight in the Z-direction and substantially perpendicularly to the spans 42 extending in the X-direction. In some embodiments, the basal end 44 and the connectors 46 may not extend substantially perpendicularly to the spans 42. For example, the basal end 44 and the connectors 46 may be curved, rather than extending straight in the Z-direction. Similarly, as shown in FIG. 3, the basal end 54 and the connectors 56 in the bent portion 50 extend straight in the Z-direction and substantially perpendicularly to the spans 52 extending in the Y-direction. In some embodiments, the basal end 54 and the connectors 56 may not extend substantially perpendicularly to the spans 52. For example, the basal end 54 and the connectors 56 may be curved, rather than extending straight in the Z-direction. Simulations performed by the inventors show that the bent portions including multiple angular U-shaped portions as in the present embodiment can reduce the load effectively.

Although the bent portion 40 in the present embodiment includes nine connectors 46, the bent portion 40 may include any number of connectors 46. For example, the bent portion 40 may include a single connector 46. However, the bent portion 40 including multiple connectors 46 alternating with one another in the X-direction across the multiple spans 42 as in the present embodiment can reduce the load more effectively. The same applies to the connectors 56 in the bent portion 50.

The simulations performed by the inventors show that the bent portions 40 and 50 each including more bends at positions closer to the rotation centers of the main substrate 10 and the lens module 20 can reduce the load on the entire flexible printed circuit board 30 more effectively. Thus, in the present embodiment, the connectors 46 in the bent portion 40 and the connectors 56 in the bent portion 50 are shorter at positions closer to the main substrate 10 in the Z-direction. More specifically, the connectors 46I, 46H, 46G, 46F, 46E, 46D, 46C, 46B, and 46A are gradually shorter in the Z-direction in this order. The connectors 56I, 56H, 56G, 56F, 56E, 56D, 56C, 56B, and 56A are gradually shorter in the Z-direction in this order.

In the present embodiment, the spans 42 in the bent portion 40 have their middles in the X-direction aligned with the middle of the main substrate 10 in the X-direction. The spans 52 in the bent portion 50 have their middles in the Y-direction shifted in the Y-direction from the middle of the main substrate 10 in the Y-direction. The bent portion 40 can thus reduce the load on the flexible printed circuit board 30 caused by the rotation about the Y-axis more effectively than the bent portion 50. The flexible printed circuit board 30 in the present embodiment is thus particularly useful when the rotation occurs more frequently about the Y-axis than about the X-axis or when the rotation occurs by a greater degree about the Y-axis than about the X-axis.

In the present embodiment, as shown in FIG. 4, the bent portion 40 and the bent portion 50 are within the main substrate 10 in a projection view on the main substrate 10. In other words, the bent portion 40 and the bent portion 50 are within the main substrate 10 when viewed in the Z-direction. Thus, the imaging unit 1 according to the present embodiment has a small footprint on the XY plane and can be installed in a narrow space.

Although the width W₁ (first width) of the bent portion 40 and the width W₂ (second width) of the bent portion 50 are the same in the present embodiment, the width W₁ of the bent portion 40 and the width W₂ of the bent portion 50 may not be the same and may be different.

As described above, the imaging unit according to one or more embodiments of the present invention may have the structure described below.

### First Structure

An imaging unit, comprising:
a main substrate having a first surface and a second surface opposite to the first surface;
a lens module including at least one lens having an optical axis in a first direction and an image sensor mounted on the first surface of the main substrate; and
a flexible printed circuit board containing wiring electrically connected to the image sensor in the lens module, the flexible printed circuit board including
   a first bent portion including bends and extending from the main substrate substantially in the first direction, the first bent portion having a first width in a second direction perpendicular to the first direction, and
   a second bent portion including bends and extending from the main substrate substantially in the first direction, the second bent portion having a second width in a third direction perpendicular to the first direction and to the second direction,
wherein the first bent portion in the flexible printed circuit board includes
   a plurality of first spans extending in the third direction and arranged in the first direction, and
   at least one first connector connecting the plurality of first spans adjacent to each other in the first direction, and
the second bent portion in the flexible printed circuit board includes
   a plurality of second spans extending in the second direction and arranged in the first direction, and
   at least one second connector connecting the plurality of second spans adjacent to each other in the first direction.

### Second Structure

The imaging unit according to the first structure, wherein
the at least one first connector and the at least one second connector extend in the first direction.

### Third Structure

The imaging unit according to the first structure or the second structure, wherein
the plurality of first spans have a same length in the third direction.

### Fourth Structure

The imaging unit according to any one of the first to third structures, wherein
the plurality of second spans have a same length in the second direction.

### Fifth Structure

The imaging unit according to any one of the first to fourth structures, wherein
the at least one first connector includes a plurality of first connectors alternating with one another in the third direction across the plurality of first spans arranged in the first direction.

### Sixth Structure

The imaging unit according to the fifth structure, wherein
the plurality of first connectors are shorter at positions closer to the main substrate in the first direction.

### Seventh Structure

The imaging unit according to any one of the first to sixth structures, wherein
the at least one second connector includes a plurality of second connectors alternating with one another in the second direction across the plurality of second spans arranged in the first direction.

### Eighth Structure

The imaging unit according to the seventh structure, wherein
the plurality of second connectors are shorter at positions closer to the main substrate in the first direction.

### Ninth Structure

The imaging unit according to any one of the first to eighth structures, wherein
the plurality of first spans have middles in the third direction aligned with a middle of the main substrate in the third direction.

### Tenth Structure

The imaging unit according to any one of the first to ninth structures, wherein
the plurality of second spans have middles in the second direction shifted in the second direction from a middle of the main substrate in the second direction.

### Eleventh Structure

The imaging unit according to any one of the first to tenth structures, wherein
the first bent portion and the second bent portion are within the main substrate when viewed in the first direction.

Although the embodiment of the present invention has been described above, the present invention is not limited to the above embodiment and may be modified variously within the scope of its technical idea.

What is claimed is:

1. An imaging unit, comprising:
a main substrate having a first surface and a second surface opposite to the first surface;
a lens module including at least one lens having an optical axis in a first direction and an image sensor mounted on the first surface of the main substrate; and
a flexible printed circuit board containing wiring electrically connected to the image sensor in the lens module, the flexible printed circuit board including
a first bent portion including bends and extending from the main substrate substantially in the first direction, the first bent portion having a first width in a second direction perpendicular to the first direction, and
a second bent portion including bends and extending from the main substrate substantially in the first direction, the second bent portion having a second width in a third direction perpendicular to the first direction and to the second direction,
wherein the first bent portion in the flexible printed circuit board includes
a plurality of first spans extending in the third direction and arranged in the first direction, and
at least one first connector connecting the plurality of first spans adjacent to each other in the first direction, and
the second bent portion in the flexible printed circuit board includes
a plurality of second spans extending in the second direction and arranged in the first direction, and
at least one second connector connecting the plurality of second spans adjacent to each other in the first direction.

2. The imaging unit according to claim 1, wherein
the at least one first connector and the at least one second connector extend in the first direction.

3. The imaging unit according to claim 1, wherein
the plurality of first spans have a same length in the third direction.

4. The imaging unit according to claim 1, wherein
the plurality of second spans have a same length in the second direction.

5. The imaging unit according to claim 1, wherein
the at least one first connector includes a plurality of first connectors alternating with one another in the third direction across the plurality of first spans arranged in the first direction.

6. The imaging unit according to claim 5, wherein
the plurality of first connectors are shorter at positions closer to the main substrate in the first direction.

7. The imaging unit according to claim 1, wherein
the at least one second connector includes a plurality of second connectors alternating with one another in the second direction across the plurality of second spans arranged in the first direction.

8. The imaging unit according to claim 7, wherein
the plurality of second connectors are shorter at positions closer to the main substrate in the first direction.

9. The imaging unit according to claim 1, wherein
the plurality of first spans have middles in the third direction aligned with a middle of the main substrate in the third direction.

10. The imaging unit according to claim 1, wherein
the plurality of second spans have middles in the second direction shifted in the second direction from a middle of the main substrate in the second direction.

11. The imaging unit according to claim 1, wherein
the first bent portion and the second bent portion are within the main substrate when viewed in the first direction.
